(19) United States
(12) Patent Application Publication
(10) Pub. No.: US 2025/0372412 A1
(43) Pub. Date: Dec. 4, 2025

(54) Fast Gas Delivery System for Enhanced Semiconductor Process Efficiency

(71) Applicant: Yang Pan, SINGAPORE (SG)

(72) Inventor: Yang Pan, SINGAPORE (SG)

(73) Assignee: Inspiring Atoms Pte Ltd, SINGAPORE (SG)

(21) Appl. No.: 18/732,779

(22) Filed: Jun. 4, 2024

(51) Int. Cl. H01L 21/67; H01J 37/32

(52) U.S. Cl. CPC H01L 21/67069; H01J 37/32449; H01J 2237/334

(57) ABSTRACT

The present invention relates to a fast gas delivery system for an atomic layer etching (ALE) process system in semiconductor manufacturing. It features a vacuum-operated chamber, an RF power generator, a substrate pedestal, and a gas delivery system using Mass Flow Controllers (MFCs). These MFCs operate in training and inference modes to ensure precise gas flow rates. This system enhances process efficiency and reduces cycle time by eliminating conventional gasbox and utilizing a streamlined gas distribution unit. The present invention can also be applied to other etching and deposition process systems beyond the ALE applications.

### BACKGROUND OF THE INVENTION

### 1. Field of the Invention

The present invention pertains to the field of semiconductor manufacturing, specifically to a fast gas delivery system for a process system. The invention focuses on an improved gas delivery system intended to reduce costs and enhance the efficiency of atomic layer etching (ALE) process systems.

### 2. Description of the Prior Art

Reactive ion etching (RIE) is a predominant technology in semiconductor manufacturing. In RIE, various species, including neutrals, radicals, and ions, concurrently influence the etching process. A key characteristic of RIE is the synergistic interaction between ion and neutral fluxes, which significantly enhances the etching rate. This synergistic effect was first described by Coburn and Winters in “Ion- and electron-assisted gas-surface chemistry—an important effect in plasma etching,” published in J. Appl. Phys., vol. 50, pages 3189-3196 (1979). They reported increased silicon etching rates when using an argon ion beam, a XeF2 neutral beam, and their combination. Effective RIE necessitates the presence of both ion and neutral fluxes to exploit this synergy. However, in modern etching processes, balancing these fluxes, particularly for etching high aspect ratio structures with dimensions shrinking to the nanometer scale, is increasingly complex. Achieving uniform results across 300 mm wafers and consistent repeatability in production pose additional challenges.

ALE has been developed to address the limitations of RIE. The ALE process system has evolved from the RIE process system, with less stringent requirements for achieving uniformity on a 300 mm wafer. However, ALE has unique requirements due to the nature of its process steps. An overview of ALE technology is presented by Karanik et al. in “Overview of atomic layer etching in the semiconductor industry” (J. Vac. Sci. Technol. A33, pages 020802 1-14, 2015), and further discussed by Lill in “Atomic layer processing: semiconductor dry etching technology” (Wiley-VCH GmbH, Boschstr. 12, 69469 Weinheim, Germany, 2021). ALE facilitates the controlled removal of material layers with atomic-level precision and is characterized as an etching technique using sequential self-limiting reactions. The basic ALE process includes two steps: surface modification and material removal. The modification creates a thin reactive layer with a defined thickness, which is easier to remove than the unmodified material. The removal step eliminates this modified layer while preserving the underlying substrate, thus resetting the surface for subsequent cycles. Material removal can be achieved using thermal energy by raising the wafer's temperature or kinetic energy from ions typically derived from inert gases. The isotropic process using thermal energy to remove modified layers is described in U.S. Pat. No. 10,208,383 to George et al. When utilizing energetic ions, the removal is conducted via a sputtering process. The anisotropic ALE process, as described in U.S. Pat. No. 10,727,073 to Tan et al., demonstrates the technology's versatility.

The standard practice in ALE involves modulating multiple gases' flow rates using mass flow controllers (MFCs). This modulation is typically dynamic, requiring constant adjustments to maintain optimal etching conditions, which adds complexity and potential for inconsistency in the etching process. Additionally, transitioning between different etching steps, such as from surface modification to sputtering, often necessitates complete gas exchanges, further prolonging the overall process cycle time.

There is a clear need for innovations in the ALE process that streamline gas management, accelerate gas exchanges, reduce cycle time, and enhance the consistency of etching outcomes. This invention addresses these needs by introducing a novel system and method for fast gas delivery into a chamber with novel applications of MFCs.

### SUMMARY

This invention introduces an ALE process system that incorporates a gas delivery system, aiming to increase operational speed and decrease costs. An anisotropic ALE process involves two sequential steps running in cycles: a surface modification step consuming a first gas and a sputtering step consuming a second gas.

In specific embodiments, a novel method involving the use of an MFC is introduced. The MFC can operate in two modes: training and inference. In training mode, the MFC conducts a training procedure involving both gases. During this procedure, the gases are evaluated at designated flow rates for the steps. A proportional integral derivative (PID) control loop adjusts the current supplied to a solenoid coil of the MFC, moving a plunger to achieve the desired flow rate for the gas. These current values are recorded in a storage unit by a controller for subsequent use. Training of the MFC can be performed before it is used in the ALE process.

When an ALE process is initiated, the MFCs are operated in inference mode. In the surface modification step, an MFC controller retrieves the value of the first solenoid coil current from the storage unit. This current, when applied to the solenoid coil, positions the plunger to yield the necessary flow rate for the first gas. In this mode, the PID control loop is inactive. As a result, the MFC's setting time is based on the current delivered to the solenoid coil, using magnetic force to position the plunger, a process that typically takes a few milliseconds compared to the much longer duration required when using a PID control loop. A plasma is generated in the chamber to create neutrals to modify the surface of a substrate.

Switching to the sputtering step, the first MFC is switched off by supplying a predetermined solenoid coil current, moving the plunger to stop the gas conduction. The controller retrieves the value of the second solenoid current from the storage unit and delivers the required current to the solenoid coil of the second MFC. The second gas is then channeled into the chamber at the designated flow rate. Subsequently, a plasma is generated, and ions are accelerated by providing a bias to a pedestal to remove the modified layer. The cycle repeats until the ALE process is completed.

Some implementations include a brief delay between turning off the first MFC and activating the second MFC, ensuring the full expulsion of the first gas from the chamber, and vice versa. Several embodiments of this invention emphasize rapid gas switching via a simplified gas delivery system, made possible by the innovative use of MFCs. This strategy accelerates the ALE process without compromising its performance.

### BRIEF DESCRIPTIONS OF DRAWINGS

For enhanced clarity, the following description refers to accompanying drawings:

FIG. 1: Illustrates a conventional ALE system.

FIG. 2: Depicts a flowchart of the operational steps in the conventional ALE system.

FIG. 3: Shows an ALE system featuring a modified gas delivery unit.

FIG. 4: Shows a functional diagram of an exemplary MFC.

FIG. 5: Shows a flowchart of the MFC operated in the training mode.

FIG. 6: Depicts a flowchart of an exemplary ALE process utilizing novel MFCs.

### DETAILED DESCRIPTIONS

To provide a thorough understanding, this description elaborates on embodiments of the present invention. While specific details are outlined for clarity, adaptations and variations consistent with the subsequent claims are considered acceptable. Selected conventional methods and components are described to emphasize the unique aspects of the invention.

The ALE process system is employed to elaborate on the inventive concepts of fast gas delivery to a chamber suitable for a vacuum-based plasma process. The inventive concept, however, can be readily applied to any processing chamber that requires fast gas delivery and exchange. The use of the ALE process system is exemplary and should not limit the scope of the present inventive concept. For example, the present inventive concept can be applied to any type of etching and deposition process system, either plasma-based or thermal-based, if fast gas delivery and exchange are required.

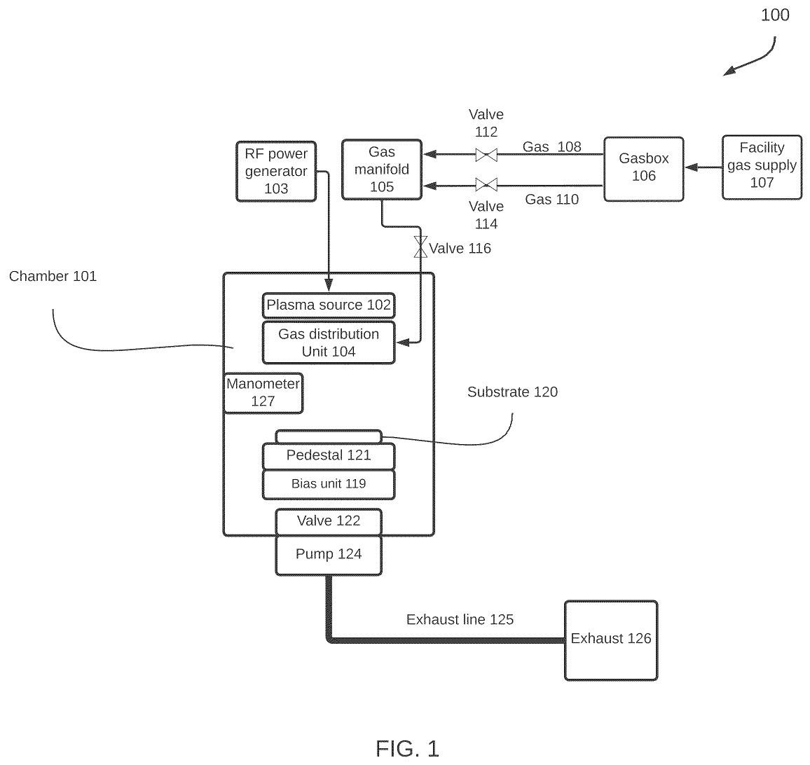

FIG. 1 illustrates a conventional ALE process system, labeled as 100. Housed within a vacuum setting, the chamber 101 is equipped with a plasma source 102, powered by its associated RF power generator 103. The plasma source 102 can adopt various designs, including transformer coupled plasma (TCP) and inductively coupled plasma (ICP). Some implementations might include a matching network (not shown) positioned between the RF power generator 103 and plasma source 102, while others might directly connect the two.

In the configuration presented in FIG. 1, a gas delivery system is depicted including a gas distribution unit 104, a gasbox 106, a gas manifold 105, and valves (112, 114, and 116). The gas distribution unit 104 draws gases from the gasbox 106 through the gas manifold 105. Based on specific design needs, this unit 104 might take the form of a showerhead or an injector. The manifold 105 combines various gases prior to their introduction to the chamber 101. Valves 112 and 114 are located between the gasbox 106 and the manifold 105 to control the flow of a first gas 108 and a second gas 110, respectively. It's important to clarify that, although only two gas lines are illustrated for clarity, multiple gases can participate in ALE processes. The first gas 108, or similarly the second gas 110, may be a single gas or a mix of various gases. Another valve 116, situated between the manifold and the distribution unit 104, governs the gas flow into the chamber 101. The gasbox 106 is connected to a central gas supply 107.

Inside the chamber 101, a pedestal 121 provides support for the substrate 120. This pedestal often resembles an electrostatic chuck (ESC), crafted specifically for etching tasks. To guarantee the desired ion energy-especially vital for etching high aspect ratio structures-a bias 119 is activated once plasma forms in the chamber. The source of this bias can either be an RF power generator linked to the pedestal 121 via a blocking capacitor or a tailored waveform generator, depending on the design parameters.

To remove gases and resultant by-products from chamber 101, a pump 124 is utilized. A valve 122, adjacent to this pump, adjusts the evacuation speed, guiding the gases towards an exhaust 126 via an exhaust line 125. Maintaining a consistent pressure within the chamber involves a balancing act between gas input and output rates. This equilibrium is further refined by a PID control loop which retrieves pressure data from a manometer 127.

In the ALE process, two separate gases (108 and 110) are typically used in two individual steps: the surface modification step and the sputtering step. These are commonly referred to as two half-cycles, combining to form one complete ALE cycle.

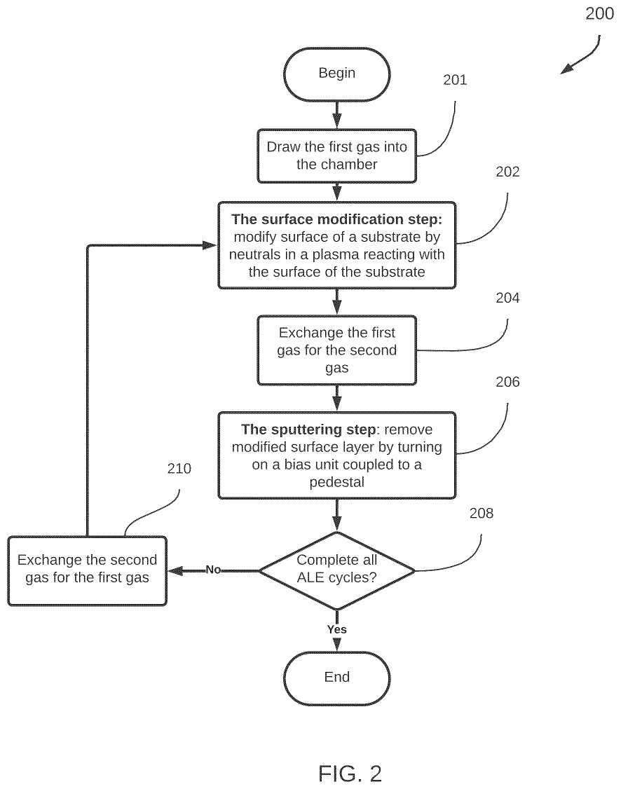

FIG. 2 details the quintessential ALE sequence, labeled as 200. In step 201, the introduction of the first gas 108 from the gasbox 106 into the chamber 101 takes place via the distribution unit 104. Step 202 chronicles the chemical alteration of the substrate's surface. As an example, chlorine gas could be employed to weaken silicon-chlorine bonds in contrast to inherent silicon bonds. Plasma, energized by the RF power generator 103 and plasma source 102, can assist in this transformation. When plasma is used during the surface modification step, the bias unit is turned off to prevent any disruptions from high-energy ions. Step 204 indicates the cessation of the surface modification step; the inflow of the first gas 108 is halted, paving the way for the introduction of the second gas 110.

Considering that each ALE cycle etches only a few monolayers of the material, multiple cycles are essential to attain the desired etch depth. In some scenarios, the number of ALE cycles can surpass a hundred, particularly when handling the high aspect ratio structures. Step 208 involves counting the cycles and comparing them to a pre-established recipe. If the necessary cycles are completed, the ALE procedure wraps up. If not, step 210 switches the second gas back to the first, marking the onset of a fresh ALE cycle.

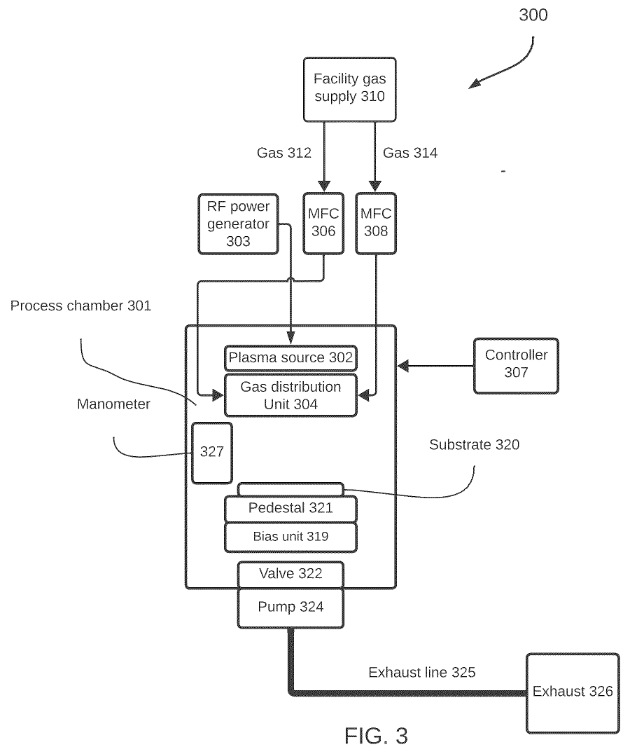

FIG. 3 showcases an embodiment, labeled as 300, of an ALE system equipped with a streamlined gas delivery system. Several striking differences are observed between this embodiment 300 and the conventional ALE process system 100 showcased in FIG. 1. A standout alteration is the absence of the gasbox, leading to a cost-effective design since gasboxes are typically high-cost subsystems.

Furthermore, the valves have been omitted. One unique aspect of the present invention is the dual functionality of MFCs, serving both as a flow rate controller and as a valve. The conventional method to adjust an MFC to a specific set point using a PID control loop, aiming for the desired flow rate, generally demands several dozen to several hundred milliseconds to reach the steady state flow rate. This duration is suboptimal for ALE processes. Innovatively, by deactivating the PID control loop and operating the MFC in an inference mode, the MFC's setting time reduces to just a few milliseconds or less.

The ALE process system 300 boasts a chamber 301, tailored for a vacuum setting. This chamber incorporates a plasma source 302, linked to an RF power generator 303. Additionally, the ALE process system 300 integrates a gas distribution unit 304, which can be either a showerhead or an injector. This gas distribution unit 304 directly taps into a facility's gas supply 310, eliminating the need for a separate gasbox and several valves. A first gas 312 is channeled into the gas distribution unit 304 via an MFC 306. Though the MFC 306 regulates the flow rate of gas 312, its innate latency makes flow rate adjustments sluggish, typically stretching over several dozen to several hundred milliseconds. In this embodiment, the flow rate of MFC 306 for gas 312 is preset, linking it to a specific driving current designated for a solenoid coil. The current is predetermined by operating the MFC 306 in a training mode before the ALE process starts. In the inference mode of the MFC after starting the ALE process, gas flow rate determination hinges on positioning a solenoid valve's plunger at a predefined location, achieved by supplying the predetermined coil current via a valve driver of the solenoid valve. The MFC's PID control loop is deactivated in the inference mode, and the redirected gas flow, gauged by a flow sensor, primarily functions to confirm the flow rate.

A controller, designated as 307, orchestrates and regulates the ALE process system 300's functions. The controller 307 deciphers a process recipe to ascertain parameters, such as flow rates for the first gas 312 and the second gas 314. It also supervises the functionalities of MFCs 306 and 308, commencing and concluding the ALE processes. In some implementations, MFCs 306 and 308 are equipped with local controllers (not shown in FIG. 3), which are operated under the directive of the controller 307.

The chamber 301's base region houses a pedestal 321, providing support to the substrate 320 during an ALE process. In numerous etching operations, an ESC is the preferred choice. Generally, plasma-generated ions don't possess the energy essential for etching contemporary semiconductor structures, notably those with high aspect ratio structures. To bolster ion energy, a bias unit 319 is usually applied to the pedestal. This can be sourced either from an RF power generator interfaced via a capacitor or a tailored waveform generator.

To expel gases and reaction residues from the chamber 301, a pump 324 is utilized, connected through a valve 322. A manometer 327 aids in assessing chamber pressure. The controller 307 synchronizes the gas injection from the distribution unit 304 and the valve 322, leveraging the pressure data from the manometer 327, ensuring a steady state chamber pressure optimal for the ALE process.

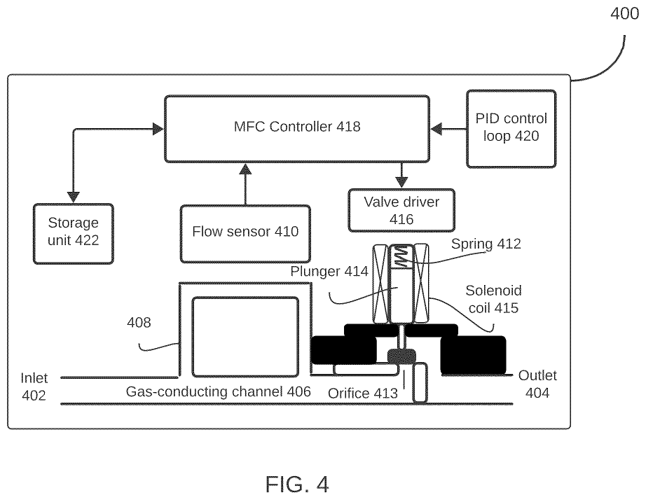

In the schematic representation of an exemplary MFC in FIG. 4, denoted as 400, the MFC comprises an inlet 402 and an outlet 404, both connected via a gas-conducting channel 406. A proportional valve, not depicted in the figure, diverts a portion of the gas to a channel 408. The diverted gas's flow rate is determined by the flow sensor 410, typically employing thermal sensing to measure the temperature differences at two designated positions along a flow path. This flow rate acts as a proxy for the overall flow rate in the gas-conducting channel 406.

The MFC 400 features a solenoid valve. This valve comprises a spring 412 that holds a plunger 414 in place. The position of the plunger 414 determines the gas conductance across orifices 413. When the plunger obstructs the channel within orifice 413, gas flow stops. The solenoid coil 415 controls the position of the plunger. When current flows through the coil, it creates a magnetic force, which, combined with the force exerted by the spring 412, determines the position of the plunger 414.

The flow sensor 410 sends its readings to the MFC controller 418. The controller compares the flow rate data to a benchmarked value in its memory, corresponding to a desired gas flow rate. If discrepancies arise between the measured flow rate and the target, the MFC controller 418 instructs the valve driver 416 to adjust the current in solenoid coil 415, thereby changing the plunger's position 414. This calibration loop continues until the measured flow rate matches the target. To expedite the process, the MFC controller 418 uses a PID control loop. This process can take several dozens to several hundred milliseconds, which isn't efficient for ALE processes.

The MFC 400 can be operated in a training mode or in an inference mode. In the training mode, the MFC controller 418 conducts a test procedure to determine the solenoid coil currents for the first and the second gases at required flow rates stipulated by an ALE process recipe. The determined current values are stored in storage unit 422 coupled to the MFC controller 418.

The MFC controller 418 switches the MFCs to their inference mode immediately after the ALE process is initiated. The PID control loop 420 is deactivated accordingly, significantly reducing the MFC's operational time. Instead of the longer adjustment phase seen in training mode, the MFCs deliver the desired gas flow rate in a few milliseconds or less in inference mode. The MFC controller 418 retrieves the stored value of the solenoid coil currents from the storage unit 422. Applying currents to solenoid coil 415 quickly sets the plunger 414 to the correct positions.

While a portion of the gas still gets rerouted to channel 408 for monitoring by the flow sensor 410, this measurement primarily serves as a verification to confirm consistency with the desired flow rate. The measured flow rates can be stored in the storage unit 422. The stored data may be consumed by controller 307 to form a trend chart. Statistical process control (SPC) methods can then be applied to monitor the stability of the MFC. If an out-of-control event is detected according to predetermined APC rules, a re-training event can be initiated.

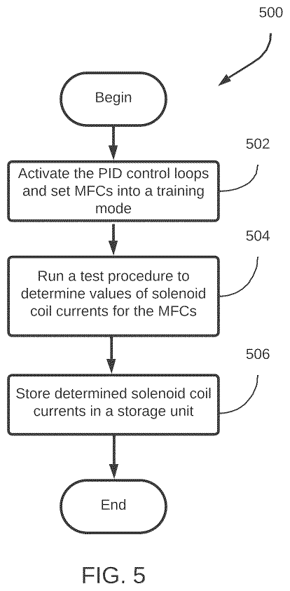

FIG. 5 illustrates a flowchart of the process 500, where the MFCs are operated in the training mode. The process begins with step 502, where the MFC controller 418 activates the PID control loop 420 and transitions the MFCs into the training mode. Subsequently, in step 504, a test procedure is conducted to determine solenoid coil currents for the first and the second MFCs, respectively. Determined values of the solenoid coil currents are stored in the storage unit 422. In some embodiments, process 500 can be executed by the controller 307. In still other embodiments, the controller 307 and the MFC controller 418 work together to execute process 500.

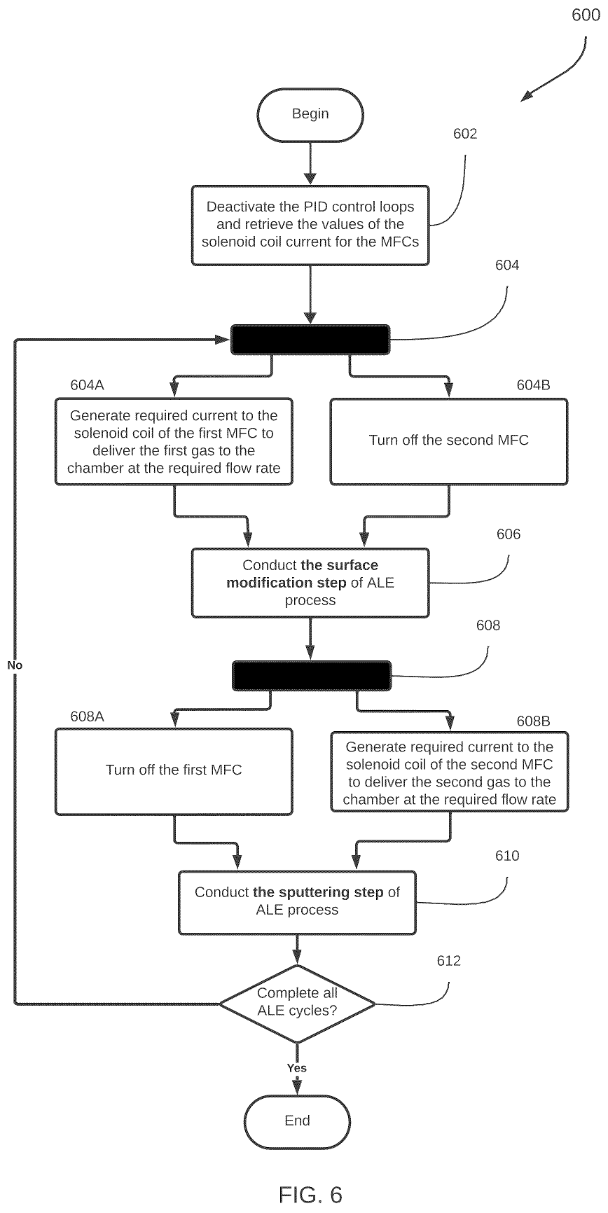

FIG. 6 elucidates the process flow 600 for the ALE process system 300. Beginning with step 602, before starting the ALE process, the controller 307 deactivates the PID control loops for both MFCs. The MFCs are set into the inference mode. Subsequently, the values of required solenoid coil current are retrieved from the storage units. Moving to step 604, it branches into two parallel actions: 604A and 604B. In 604A, the first MFC controller directs its valve driver to generate the first solenoid coil current to deliver the first gas at the required flow rate. Concurrently, in step 604B, the second MFC is turned off to stop the second gas channel into the chamber.

The surface modification step is conducted in step 606. During the surface modification step, the plasma source 302 in chamber 301 receives an RF power from the RF power generator 303. Neutrals created in the plasma in the chamber diffuse to the surface of the substrate and react with the atoms in the surface to form a modified layer with weakened bonds.

Next, in step 608, there are two simultaneous actions: 608A and 608B. In 608A, the first MFC reduces the flow rate of the first gas to zero. In contrast, in 608B, the second MFC controller directs its valve driver to generate the second solenoid coil current to deliver the second gas at the required flow rate.

These two parallel operations (606A and 606B) can either be initiated at the same time or, in some implementations, a short delay might be introduced between them to ensure that the first gas is fully cleared from the chamber before the second gas is introduced.

Following this, step 610 represents the sputtering step of the ALE process. Here, the altered surface layer is removed due to the action of energetic ions produced by the plasma and the bias unit. This completes one round of the ALE process.

Lastly, in step 612, the controller 307 checks the number of ALE cycles completed and determines whether to initiate another cycle based on the process recipe's requirements.

1. An ALE process system, comprising:
a chamber designed to operate in a vacuum environment;
a plasma source coupled to an RF power generator;
a pedestal for holding a substrate;
a bias unit coupled to the pedestal;
a gas delivery system including a first MFC designated to regulate a first gas and a second MFC designated to regulate a second gas, wherein the MFCs further include solenoid valves comprising solenoid coils; and
a controller operating the MFCs in a training mode or an inference mode,
wherein in the training mode, the controller measures solenoid coil currents for required flow rates for the first and the second gases and stores the current values in a storage unit, and wherein in the inference mode, the controller retrieves the current values and delivers the currents to the solenoid coils of the first and the second MFCs, respectively, through a valve driver to achieve required flow rates for the first and the second gases.

2. The system of claim 1, wherein a proportional-integral-derivative (PID) control loop is activated in the training mode.

3. The system of claim 1, wherein a PID control loop is deactivated in the inference mode.

4. The system of claim 1, wherein the first or the second MFCs can be operated as valves.

5. The system of claim 1, wherein the system further operates in a surface modification step and a sputtering step sequentially for the ALE process.

6. The system of claim 5, wherein the surface modification step consumes only the first gas regulated by the first MFC.

7. The system of claim 5, wherein the sputtering step consumes only the second gas regulated by the second MFC.

8. The system of claim 1, wherein the gases are supplied directly from a facility gas source, bypassing the need for a gasbox.

9. The system of claim 1, wherein the gas delivery system further includes a gas distribution unit.

10. The system of claim 9, wherein the gas distribution unit is either a showerhead or an injector.

11. A method for implementing an ALE process within a chamber, the method comprising:
a) deactivating PID control loops and retrieving stored values of solenoid coil currents for the first and the second MFCs;
b) generating required current to the solenoid coil of the first MFC to deliver the first gas to the chamber at the required flow rate and turning off the second MFC;
c) conducting a surface modification step for the ALE process;
d) generating required current to the solenoid coil of the second MFC to deliver the second gas to the chamber at the required flow rate and turning off the first MFC;
e) conducting a sputtering step of the ALE process; and
f) repeating steps a) to e) until the ALE process is completed.

12. The method of claim 11, further including a step of measuring the solenoid coil currents while operating the MFCs in a training mode, wherein the PID control loops are activated.

13. The method of claim 12, wherein the training mode is conducted before the ALE process is initiated.

14. The method of claim 11, wherein in step b), the operations of generating the solenoid current for the first MFC and turning off the second MFC are synchronized.

15. The method of claim 11, wherein in step d), the operations of generating the solenoid current for the second MFC and turning off the first MFC are synchronized.

16. A gas delivery system tailored for an ALE process, comprising:
a first and a second MFC, wherein the MFCs are calibrated to specific driving currents for their respective solenoid valves, enabling them to achieve flow rates as detailed in a process recipe for a first and a second gas, wherein the determination of these driving currents is based upon conducting a test procedure while operating the MFCs in a training mode before the ALE process is initiated.

17. The system of claim 16, wherein associated PID control loops of the MFCs are rendered inactive during the ALE process.

18. The system of claim 16, wherein the first and second gases are channeled directly from a facility gas source, eliminating the need for a gasbox.

19. The system of claim 16, wherein the MFCs possess the capability to function as a valve, facilitated by a plunger within the solenoid valve entirely scaling an orifice present in the gas flow pathway.

20. The system of claim 16, wherein the gas delivery system further includes a gas distribution unit.
